(19) United States
(12) Patent Application Publication
(10) Pub. No.: US 2025/0185480 A1
(43) Pub. Date: Jun. 5, 2025

(54) DISPLAY APPARATUS

(71) Applicant: Samsung Display Co., Ltd., Yongin-si (KR)

(72) Inventors: Joon Huh, Yongin-si (KR); Sanggeun Kim, Yongin-si (KR); Sunhyung Choi, Yongin-si (KR); Wonjin Choi, Yongin-si (KR)

(21) Appl. No.: 18/896,612

(22) Filed: Sep. 25, 2024

(30) Foreign Application Priority Data
Dec. 1, 2023 (KR) 10-2023-0172733

(51) Int. Cl. H10K 59/131; H10K 59/88

(52) U.S. Cl. CPC H10K 59/131; H10K 59/88

(57) ABSTRACT

A display apparatus includes a first pad portion at a side of a substrate and including dummy pads, a second pad portion including test pads electrically connected to the dummy pads, a driving integrated circuit electrically connected to the first pad portion, and a printed circuit board electrically connected to the second pad portion and including test terminals electrically connected to the test pads, wherein the dummy pads include first and second dummy pads electrically connected to each other, wherein the test pads include a first test pad electrically connected to the first dummy pad, a second test pad electrically connected to the first dummy pad, and a third test pad electrically connected to the second dummy pad, and wherein the test terminals include a 1st-1 test terminal and a 1st-2 test terminal electrically connected to the first test pad.

### CROSS-REFERENCE TO RELATED APPLICATION

The present application claims priority to, and the benefit of, Korean Patent Application No. 10-2023-0172733, filed on Dec. 1, 2023, in the Korean Intellectual Property Office, the entire disclosure of which is incorporated by reference.

### BACKGROUND

### 1. Field

One or more embodiments relate to a display apparatus.

### 2. Description of the Related Art

A display apparatus visually displays data. The display apparatus may include a substrate divided into a display area and a peripheral area. In the display area, a scan line and a data line are formed to be insulated from each other and a plurality of pixels may be included. Also, in the display area, a thin-film transistor corresponding to each of the plurality of pixels and a sub-pixel electrode electrically connected to the thin-film transistor may be provided. Also, an opposite electrode commonly provided for the pixels may be provided in the display area. In the peripheral area, there may be provided various lines, a scan driver, a data driver, a controller, a pad portion, etc., configured to transmit electrical signals to the display area.

A plurality of signal pads may be provided in a pad portion of a display apparatus to interface an electrical signal with an external driving device. The driving device may include a chip or a film configured to drive a display panel, for example, a driving integrated circuit (DIC), a flexible printed circuit (FPC) film, etc. Examples of a method of mounting the chip or the film, which is the driving device, on the display panel, may include a chip-on-glass (COG) method, a chip-on-plastic (COP) method, a film-on-glass (FOG) method, and a film-on-plastic (FOP) method. When the chip or the film are coupled to the display panel, contact resistance may occur.

### SUMMARY

One or more embodiments include a display apparatus having a structure to reduce the number of pads configured to measure the contact resistance. However, this objective is an example and does not limit the scope of the disclosure.

Additional aspects will be set forth in part in the description which follows and, in part, will be apparent from the description, or may be learned by practice of the presented embodiments of the disclosure.

According to one or more embodiments, a display apparatus includes a substrate defining a display area including pixels, and a peripheral area surrounding at least a portion of the display area in plan view, a first pad portion at a side of the substrate, and including dummy pads, a second pad portion including test pads electrically connected to the dummy pads, a driving integrated circuit electrically connected to the first pad portion, and a printed circuit board electrically connected to the second pad portion, and including test terminals electrically connected to the test pads, wherein the dummy pads include a first dummy pad and a second dummy pad electrically connected to each other by an internal connection line in the driving integrated circuit, wherein the test pads include a first test pad electrically connected to the first dummy pad through a first connection line, a second test pad electrically connected to the first dummy pad through a second connection line, and a third test pad electrically connected to the second dummy pad through a third connection line, and wherein the test terminals include a 1^{st}-1 test terminal and a 1^{st}-2 test terminal that are electrically connected to the first test pad.

The dummy pads may further include a third dummy pad electrically connected to the second dummy pad through the internal connection line, wherein the test pads further include a fourth test pad electrically connected to the third dummy pad through a fourth connection line.

The internal connection line may be electrically connected to a surface of the first dummy pad, to a surface of the second dummy pad, and to a surface of the third dummy pad, wherein the first connection line and the second connection line are electrically connected to another surface of the first dummy pad, wherein the third connection line is electrically connected to another surface of the second dummy pad, and wherein the fourth connection line is electrically connected to another surface of the third dummy pad.

The test terminals may further include a second test terminal electrically connected to the second test pad, a third test terminal electrically connected to the third test pad, and a fourth test terminal electrically connected to the fourth test pad.

The 1^{st}-2 test terminal may be electrically connected to a first node between the 1^{st}-1 test terminal and the first test pad, wherein the second test terminal is electrically connected to a second node between the first test pad and the first dummy pad, and wherein the third test terminal is electrically connected to a third node between the first dummy pad and the third dummy pad.

The dummy pads may further include a third dummy pad electrically connected to the second dummy pad through the internal connection line, wherein the test pads further include a fourth test pad electrically connected to the second dummy pad through a fourth connection line, and a fifth test pad electrically connected to the third dummy pad through a fifth connection line.

The internal connection line may be electrically connected to a surface of the first dummy pad, to a surface of the second dummy pad, and to a surface of the third dummy pad, wherein the first connection line and the second connection line are electrically connected to another surface of the first dummy pad, wherein the third connection line and the fourth connection line are electrically connected to another surface of the second dummy pad, and wherein the fifth connection line is electrically connected to another surface of the third dummy pad.

The test terminals may further include a second test terminal electrically connected to the second test pad, a third test terminal electrically connected to the third test pad, a fourth test terminal electrically connected to the fourth test pad, and a fifth test terminal electrically connected to the fifth test pad.

The second test terminal may be connected to a fourth node between the first test pad and the second test pad, wherein the 1^{st}-2 test terminal is connected to a fifth node between the 1^{st}-1 test terminal and the first test pad.

The fifth test terminal may be connected to a sixth node between the first dummy pad and the second dummy pad, wherein the fourth test terminal is connected to a seventh node between the second dummy pad and the third test terminal.

The dummy pads may be insulated from the pixels.

The first pad portion may include first signal pads electrically connected to the pixels, wherein the second pad portion includes second signal pads electrically connected to the first signal pads.

The driving integrated circuit may include contact pads respectively corresponding to the dummy pads.

A bending axis may be defined between the first pad portion and the pixels, wherein the display apparatus is bent with respect to the bending axis.

According to one or more embodiments, a display apparatus includes a pixels, a first pad portion including dummy pads insulated from the pixels, a second pad portion including test pads electrically connected to the dummy pads, a driving integrated circuit electrically connected to the first pad portion, and a printed circuit board electrically connected to the second pad portion, and including test terminals electrically connected to the test pads, wherein the dummy pads include a first dummy pad, a second dummy pad, and a third dummy pad that are electrically connected to each other through an internal connection line in the driving integrated circuit, wherein the test pads include a first test pad and a second test pad that are electrically connected to the first dummy pad, a third test pad electrically connected to the second dummy pad, and a fourth test pad electrically connected to the third dummy pad, and wherein the test terminals include a 1^{st}-1 test terminal connected to the first test pad, a 1^{st}-2 test terminal connected to a first node between the 1^{st}-1 test terminal and the first test pad, a second test terminal connected to a second node between the first test pad and the first dummy pad, and a third test terminal connected to a third node between the first dummy pad and the third dummy pad.

The display apparatus may further include a first connection line connecting the first test pad to the first dummy pad, a second connection line connecting the second test pad to the first dummy pad, a third connection line connecting the third test pad to the second dummy pad, and a fourth connection line connecting the fourth test pad to the third dummy pad.

The internal connection line is integrally located on a surface of the first dummy pad, on a surface of the second dummy pad, and on a surface of the third dummy pad, wherein the first connection line and the second connection line are electrically connected to another surface of the first dummy pad, wherein the third connection line is electrically connected to another surface of the second dummy pad, and wherein the fourth connection line is electrically connected to another surface of the third dummy pad.

The driving integrated circuit may be mounted on the first pad portion by a chip-on-glass (COG) method or a chip-on-plastic (COP) method.

The printed circuit board may be mounted on the second pad portion by a film-on-glass (FOG) method or a film-on-plastic (FOP) method.

The first pad portion may include first signal pads electrically connected to the pixels, wherein the second pad portion includes second signal pads electrically connected to the first signal pads.

### BRIEF DESCRIPTION OF THE DRAWINGS

The above and other aspects of embodiments of the disclosure will be more apparent from the following description taken in conjunction with the accompanying drawings, in which:

FIG. 1 is a schematic plan view of a display apparatus according to one or more embodiments;

FIG. 2 is a schematic cross-sectional view of a display area of a display apparatus according to one or more embodiments;

FIG. 3 illustrates first pads of a first pad portion according to one or more embodiments;

FIG. 4 illustrates second pads of a second pad portion according to one or more embodiments;

FIG. 5 is a schematic cross-sectional view of the display apparatus of FIG. 1 taken along the line II-II′ of FIG. 1;

FIG. 6 is a perspective view of a connection structure of test terminals, dummy pads, and test pads, according to one or more embodiments;

FIG. 7 is a perspective view for describing a method of measuring contact resistance in the connection structure of FIG. 6;

FIG. 8 is a schematic circuit diagram for describing a method of measuring contact resistance of a display apparatus, according to one or more embodiments;

FIG. 9A is a perspective view for describing a method of measuring contact resistance, according to a comparative example;

FIGS. 9B and 9C are schematic circuit diagrams for describing the method of measuring contact resistance according to the comparative one or more embodiments corresponding to the FIG. 9A;

FIG. 10 is a perspective view of a connection structure of test terminals, dummy pads, and test pads, according to one or more embodiments; and

FIGS. 11A and 11B are perspective views for describing a method of measuring contact resistance in the connection structure of FIG. 10.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present.

The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

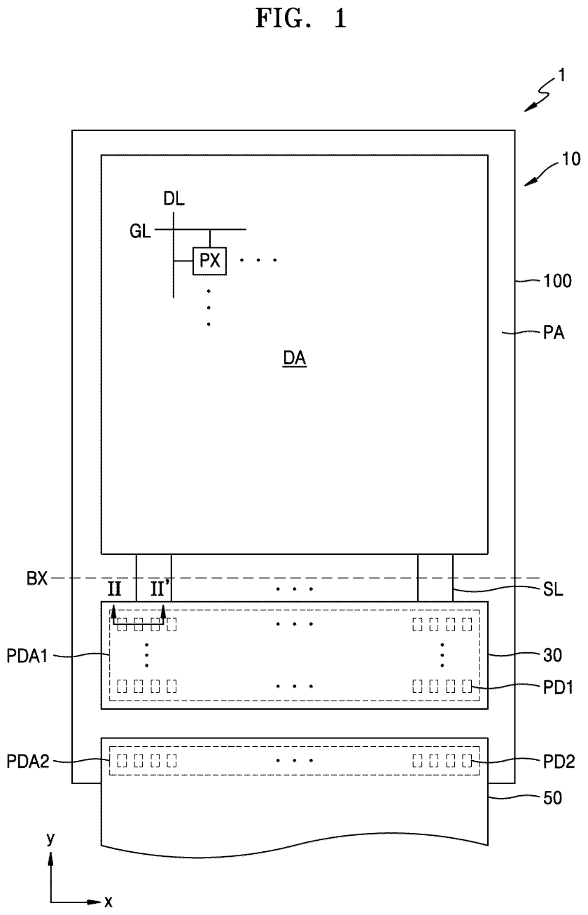

FIG. 1 is a schematic plan view of a display apparatus 1 according to one or more embodiments.

Referring to FIG. 1, the display apparatus 1 may include a display panel 10. According to one or more embodiments, the display apparatus 1 may include an organic light-emitting display apparatus. According to one or more other embodiments, the display apparatus 1 may include a liquid-crystal display, a field-emission display (FED), or an electronic paper display.

The display area DA for displaying an image, and a peripheral area PA extending outside the display area DA (e.g., in plan view) may be arranged in the substrate 100. The display area DA may include a plurality of pixels PX each including a light-emitting diode (for example, an organic light-emitting diode) electrically connected to a thin-film transistor. The pixels PX may be connected to a gate line GL arranged on the display panel 10 to extend in a first direction (e.g., x direction), and to a data line DL arranged on the display panel 10 to cross the gate line GL and extend in a second direction (e.g., y direction).

The pixels PX may include a red pixel for emitting red light, a green pixel for emitting green light, and a blue pixel for emitting blue light. However, according to one or more embodiments, the pixels PX are not limited to the pixels emitting the red, blue, and green light, and may include a pixel for emitting white light or other colors of light. The pixel PX may include a pixel circuit and a light-emitting device connected to the pixel circuit and emitting light. The pixel circuit may include at least one thin-film transistor and at least one capacitor.

The peripheral area PA may be where the plurality of pixels are not arranged, and may surround the display area DA (e.g., in plan view). The peripheral area PA may include a bending area in which the display panel 10 may be bent in one direction, and a pad area extending outside the bending area.

The bending area may include a bending axis BX defined between a first pad portion PDA1 and the display area DA. The display panel 10 may be bent in a direction with respect to the bending axis BX.

The pad area may include the first pad portion PDA1 and a second pad portion PDA2. The first pad portion PDA1 may include a plurality of first pads PD1. The second pad portion PDA2 may include a plurality of second pads PD2. The first pad portion PDA1 and the second pad portion PDA2 may be arranged in the peripheral area PA toward one side of the display area DA. For example, as illustrated in FIG. 1, the first pad portion PDA1 and the second pad portion PDA2 may be arranged to be adjacent to one side of the display area DA (e.g., a bottom side in plan view).

A driving integrated circuit 30 may be located on the first pad portion PDA1. The display panel 10 may include a plurality of signal lines SL connected to the first pad portions PD1, and may transmit a signal of the driving integrated circuit 30 to the pixels PX. The signal lines SL may include the gate line GL and the data line DL. The driving integrated circuit 30 may be configured to generate a scan signal and a data signal in response to a driving power supply and externally supplied signals, and may supply the scan signal and the data signal to the gate line GL and the data line DL, respectively. To this end, the driving integrated circuit 30 may include one or more scan drivers configured to generate a scan signal, and one or more data drivers configured to generate a data signal.

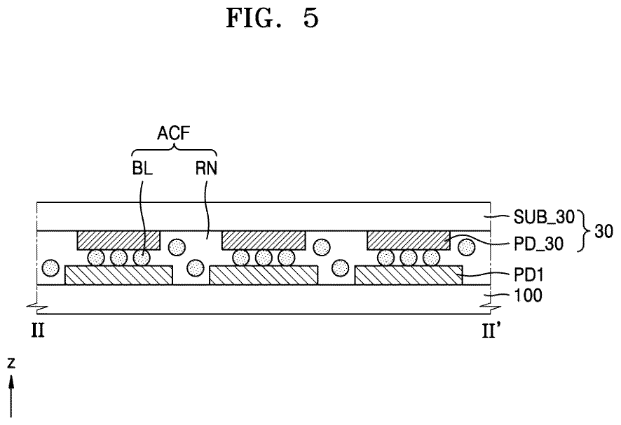

The driving integrated circuit 30 may be mounted on the first pad portion PDA1 by a chip-on-glass (COG) method or a chip-on-plastic (COP) method. The driving integrated circuit 30 may include contact pads (for example, a bump, a conductive ball, a conductive pin, etc.), which may be connected to the first pads PD1 of the first pad portion PDA1. Contact pads PD_30 (FIG. 5) of the driving integrated circuit 30 may be provided in one-on-one correspondence to the first pads PD1 of the first pad portion PDA1. The first pad portion PDA1 and the driving integrated circuit 30 may be connected to each other as the first pads PD1 and the contact pads PD_30 are coupled to each other, and due to this coupling, contact resistance (or COG/COP resistance) may occur.

A printed circuit board 50 may be located on the second pad portion PDA2. The printed circuit board 50 may include a flexible printed circuit (FPC) film. The printed circuit board 50 may be configured to generate various control signals by receiving a driving signal from an external driving circuit, and may drive the pixel PX and/or the driving integrated circuit 30 according to the control signals.

The printed circuit board 50 may be mounted on the second pad portion PDA2 by a film-on-glass (FOG) method or a film-on-plastic (FOP) method. The printed circuit board 50 may include contact pads (for example, a bump, a conductive ball, a conductive pin, etc.), which may be connected to the second pads PD2 of the second pad portion PDA2. The contact pads of the printed circuit board 50 may be provided in one-on-one correspondence to the second pads PD2 of the second pad portion PDA2. The second pad portion PDA2 and the printed circuit board 50 may be connected to each other as the second pads PD2 and the contact pads are coupled to each other and due to this coupling, contact resistance (or FOG/FOP resistance) may occur.

FIG. 1 illustrates according to one or more embodiments that the driving integrated circuit 30 and the printed circuit board 50 are provided separately from each other. However, the driving integrated circuit 30 may be formed in the printed circuit board 50, and the printed circuit board 50 including the driving integrated circuit 30 may be mounted on the display panel 10.

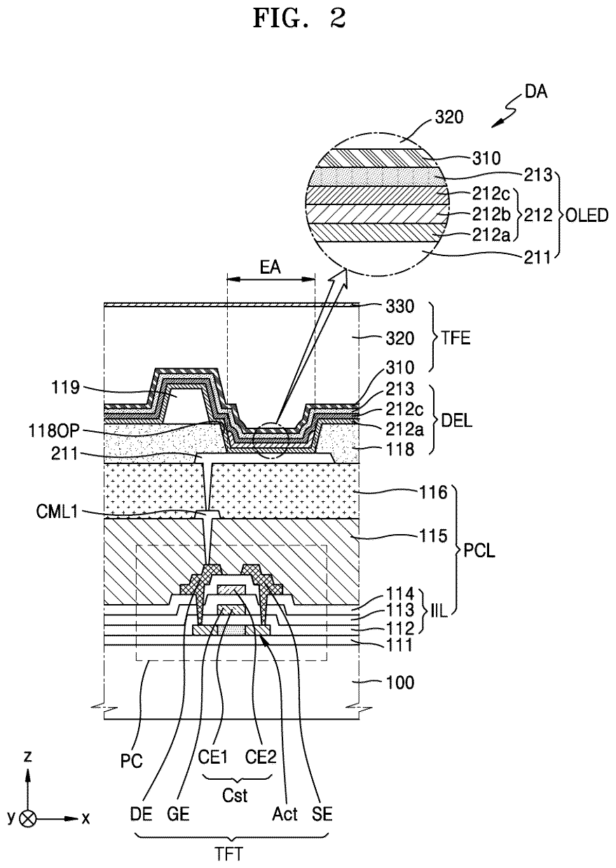

FIG. 2 is a schematic cross-sectional view of a display area of a display apparatus according to one or more embodiments.

Referring to FIG. 2, a display panel may include a substrate 100, a buffer layer 111, a pixel circuit layer PCL, a display element layer DEL, and a thin-film encapsulation layer TFE. The display panel 10 may include a substrate 100 including a plurality of pixels, a pixel circuit layer PCL in which a thin-film transistor TFT is arranged, a display element layer DEL in which an organic light-emitting device EL is arranged, and a thin-film encapsulation layer TFE covering the organic light-emitting device EL. The pixel circuit layer PCL and the display element layer DEL may be located on the substrate 100 and the thin-film encapsulation layer TFE may be located on the display element layer DEL. The pixel circuit layer PCL and the display element layer DEL may be arranged in a display area DA and the thin-film encapsulation layer TFE may cover the display area DA. In one or more embodiments, functional films, such as a polarization layer, a touch sensing unit, a cover window, etc., may be located on the thin-film encapsulation layer TFE.

The buffer layer 111 may include an inorganic insulating material, such as SiNₓ, SiON, and SiO₂, and may include a single layer or layers including the inorganic insulating material described above.

The pixel circuit layer PCL may be located on the buffer layer 111. The pixel circuit layer PCL may include a thin-film transistor TFT included in a pixel circuit PC, and also may include an inorganic insulating layer IIL, a first planarization layer 115, and a second planarization layer 116 that are arranged below or/and above elements of the thin-film transistor TFT. The inorganic insulating layer IIL may include a first gate-insulating layer 112, a second gate-insulating layer 113, and an interlayer insulating layer 114.

The thin film transistor TFT may include a semiconductor layer Act and the semiconductor layer Act may include polysilicon. Alternatively, the semiconductor layer Act may include amorphous silicon, an oxide semiconductor, or an organic semiconductor. The semiconductor layer Act may include a channel area, a drain area and a source area arranged at both sides of the channel area, respectively. A gate electrode GE may overlap the channel area.

The gate electrode GE may include a low-resistance metal material. The gate electrode GE may include a conductive material including Mo, Al, Cu, Ti, etc. and may include layers or a single layer including the conductive materials described above.

The first gate-insulating layer 112 between the semiconductor layer Act and the gate electrode GE may include an inorganic insulating material, such as SiOₓ, SiNₓ, SiON, aluminum oxide, titanium oxide, tantalum oxide, hafnium oxide, or zinc oxide.

The second gate-insulating layer 113 may be provided to cover the gate electrode GE. Similarly to the first gate-insulating layer 112, the second gate-insulating layer 113 may include an inorganic insulating material, such as SiOₓ, SiNₓ, SiON, aluminum oxide, titanium oxide, tantalum oxide, hafnium oxide, or zinc oxide.

An upper electrode CE2 of a storage capacitor Cst may be located above the second gate-insulating layer 113. The upper electrode CE2 may overlap the gate electrode GE therebelow. Here, the gate electrode GE and the upper electrode CE2 overlapping each other with the second gate-insulating layer 113 therebetween may form the storage capacitor Cst of the pixel circuit PC. That is, the gate electrode GE may function as a lower electrode CE1 of the storage capacitor Cst.

As described above, the storage capacitor Cst and the thin-film transistor TFT may be formed to overlap each other. According to some embodiments, the storage capacitor Cst may not be formed to overlap the thin-film transistor TFT.

The upper electrode CE2 may include Al, Pt, Pd, Ag, Mg, Au, Ni, Nd, Ir, Cr, Ca, Mo, Ti, W, and/or Cu, and may include a single layer or layers including the material described above.

The interlayer insulating layer 114 may cover the upper electrode CE2. The interlayer insulating layer 114 may include SiOₓ, SiNₓ, SiON, aluminum oxide, titanium oxide, tantalum oxide, hafnium oxide, or zinc oxide. The interlayer insulating layer 114 may include a single layer or layers including the inorganic insulating material described above.

Each of a drain electrode DE and a source electrode SE may be located on the interlayer insulating layer 114. The drain electrode DE and the source electrode SE may include a highly conductive material. The drain electrode DE and the source electrode SE may include a conductive material including Mo, Al, Cu, Ti, etc., and may include layers or a single layer including the materials described above. According to one or more embodiments, the drain electrode DE and the source electrode SE may have a multi-layered structure of Ti/Al/Ti.

The first planarization layer 115 may be arranged to cover the drain electrode DE and the source electrode SE. The first planarization layer 115 may include an organic insulating layer. The first planarization layer 115 may include an organic insulating material, such as a general-purpose polymer (e.g., polymethylmethacrylate (PMMA) or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A first connection electrode CML1 may be arranged on the first planarization layer 115. Here, the first connection electrode CML1 may be connected to the drain electrode DE or the source electrode SE through a contact hole of the first planarization layer 115. The first connection electrode CML1 may include a highly conductive material. The first connection electrode CML1 may include a conductive material including Mo, Al, Cu, Ti, etc., and may include layers or a single layer including the conductive materials described above. According to one or more embodiments, the first connection electrode CML1 may have a multi-layered structure of Ti/Al/Ti.

The second planarization layer 116 may cover the first connection electrode CML1. The second planarization layer 116 may include an organic insulating layer. The second planarization layer 116 may include an organic insulating material, such as a general-purpose polymer (e.g., PMMA or PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be located on the pixel circuit layer PCL. The display element layer DEL may include an organic light-emitting diode OLED, and a pixel electrode 211 of the organic light-emitting diode OLED may be electrically connected to the first connection electrode CML1 through a contact hole of the second planarization layer 116.

The pixel electrode 211 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to one or more other embodiments, the pixel electrode 211 may include a reflective layer including Ag, Mg, Al, Pt, Pd, Au, Ni, Nd, Ir, Cr, or a compound thereof. According to one or more other embodiments, the pixel electrode 211 may further include a layer including ITO, IZO, ZnO, or In₂O₃ above/below the reflective layer described above.

A bank layer (e.g., a pixel-defining layer) 118, which defines an opening 118OP exposing a central portion of the pixel electrode 211, may be located on the pixel electrode 211. The bank layer 118 may include an organic insulating material and/or an inorganic insulating material. The opening 118OP may define an emission area (hereinafter, referred to as an emission area EA) of light emitted from the organic light-emitting diode OLED. For example, a width of the opening 118OP may correspond to a width of the emission area EA.

A spacer 119 may be located on the bank layer 118. The spacer 119 may be provided to reduce or prevent the likelihood of fracture of the substrate 100 when the display apparatus is manufactured. In a manufacturing process of the display panel, a mask sheet may be used. Here, the likelihood of damage to, or a fracture of, a portion of the substrate 100, which may be caused by the mask sheet when a deposition material is deposited on the substrate 100, because the mask sheet may be inserted into the opening 118OP of the bank layer 118 or may adhere to the bank layer 118, may be reduced or prevented.

The spacer 119 may include an organic insulating material, such as polyimide. Alternatively, the spacer 119 may include an inorganic insulating material, such as SiNx or SiO₂, or may include an organic insulating material and an inorganic insulating material.

According to one or more embodiments, the spacer 119 may include a material that is different from a material of the bank layer 118. Alternatively, according to one or more other embodiments, the spacer 119 may include a material that is the same as a material of the bank layer 118, and in this case, the bank layer 118 and the spacer 119 may be formed together by a mask process using a halftone mask, etc.

An intermediate layer 212 may located on the bank layer 118. The intermediate layer 212 may include an emission layer 212b arranged in the opening 118OP of the bank layer 118. The emission layer 212b may include a high molecular-weight or low molecular-weight organic material emitting a predetermined color of light.

A first functional layer 212a and a second functional layer 212c may be arranged above and below the emission layer 212b, respectively. The first functional layer 212a may include, for example, a hole transport layer (HTL), or an HTL and a hole injection layer (HIL). The second functional layer 212c may be arranged above the emission layer 212b and may be optionally arranged. The second functional layer 212c may include an electron transport layer (ETL) and/or an electron injection layer (EIL). The first functional layer 212a and/or the second functional layer 212c may be a common layer(s) formed to entirely cover the substrate 100, like an opposite electrode 213 to be described below.

The opposite electrode 213 may include a conductive material having a low work function. For example, the opposite electrode 213 may include a (semi) transparent layer including Ag, Mg, Al, Pt, Pd, Au, Ni, Nd, Ir, Cr, Li, Ca, or an alloy thereof. Alternatively, the opposite electrode 213 may further include a layer including ITO, IZO, ZnO, or In₂O₃ on the (semi) transparent layer including the materials described above.

According to some embodiments, a capping layer may further be arranged on the opposite electrode 213. The capping layer may include LiF, an inorganic material, or/and an organic material.

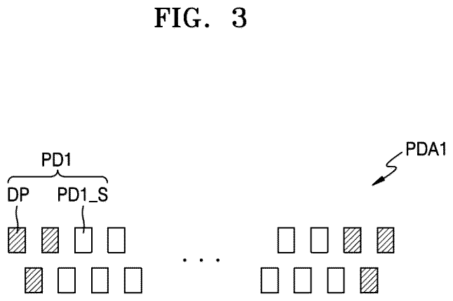

The thin-film encapsulation layer TFE may be located on the opposite electrode 213. According to one or more embodiments, the thin-film encapsulation layer TFE may include at least one inorganic encapsulation layer and at least one organic encapsulation layer. FIG. 3 illustrates that the thin-film encapsulation layer TFE may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, ZnO, SiOₓ, SiNₓ, and SiON. The organic encapsulation layer 320 may include a polymer-based material. The polymer-based material may include acryl-based resins, epoxy-based resins, polyimide, polyethylene, etc. According to one or more embodiments, the organic encapsulation layer 320 may include acrylate.

In one or more embodiments, a touch electrode layer may be arranged on the thin-film encapsulation layer TFE, and an optical functional layer may be arranged on the touch electrode layer. The touch electrode layer may obtain coordinate information based on an external input, for example, a touch event. The optical functional layer may reduce a reflectivity of light (external light) incident toward a display apparatus from the outside and/or may improve a color purity of light emitted from the display apparatus. According to one or more embodiments, the optical functional layer may include a phase retarder and a polarizer. The phase retarder may include a film-type phase retarder or a liquid crystal coating-type phase retarder, and may include a λ/2 phase retarder and/or a λ/4 phase retarder. The polarizer may also include a film-type polarizer or a liquid crystal coating-type polarizer. The film-type polarizer may include an elongation-type synthetic resin film, and the liquid crystal coating-type polarizer may include liquid crystals arranged in a certain shape. The phase retarder and the polarizer may further include a protective film.

According to one or more other embodiments, the optical functional layer may include a black matrix and color filters. The color filters may be arranged by considering a color of light emitted from each of pixels of the display apparatus. Each of the color filters may include a red, green, or blue pigment or dye. Alternatively, each of the color filters may further include quantum dots, in addition to the pigment or the dye described above. Alternatively, some of the color filters may not include the pigment or the dye described above and may include scattered particles, such as oxide titanium.

According to one or more other embodiments, the optical functional layer may include a destructive interference structure. The destructive interference structure may include a first reflective layer and a second reflective layer arranged on different layers from each other. First reflective light and second reflective light reflected from the first reflective layer and the second reflective layer, respectively, may destructively interfere, and thus, the reflectivity of external light may be decreased.

An adhesion member may be arranged between the touch electrode layer and the optical functional layer. The adhesion member may not be limited to particular types, and may be implemented as general members known in the art. The adhesion member may include a pressure sensitive adhesive (PSA).

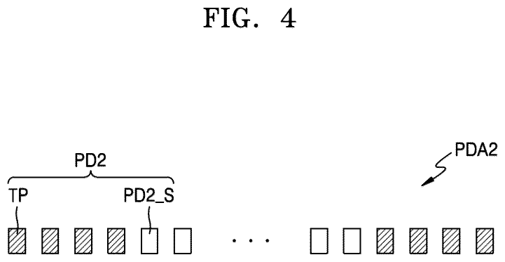

FIG. 3 illustrates the first pads PD1 of the first pad portion PDA1 according to one or more embodiments, and FIG. 4 illustrates the second pads PD2 of the second pad portion PDA2 according to one or more embodiments.

Referring to FIG. 3, the first pad portion PDA1 may include the plurality of first pads PD1. The first pads PD1 may include first signal pads PD1_S and a plurality of dummy pads DP.

The first signal pads PD1_S may be electrically connected to the pixels PX (see FIG. 1). The first signal pads PD1_S may be electrically connected to the signal lines SL (see FIG. 1), and may transmit a signal received from the driving integrated circuit 30 to the pixels PX (see FIG. 1). The first signal pads PD1_S may be directly connected to the pixels PX (see FIG. 1), or may be connected to the pixels PX (see FIG. 1) through the driving integrated circuit 30.

The dummy pads DP may be provided to measure the contact resistance. The dummy pads DP may be insulated from the pixels PX (see FIG. 1). The dummy pads DP may be not connected to the signal lines SL (see FIG. 1). According to one or more other embodiments, a dummy gate line or a dummy data line may be formed in the display panel 10, and the dummy pads DP may be connected to the dummy gate line or the dummy data line. According to one or more other embodiments, the dummy pads DP may be connected to the signal lines SL (see FIG. 1) of the display panel 10, and a switch may be provided in the signal lines SL (see FIG. 1) connected to the dummy pads DP.

The first signal pads PD1_S and the dummy pads DP may be formed by the same process. The first signal pads PD1_S and the dummy pads DP may include a conductive material. For example, the first signal pads PD1_S and the dummy pads DP may include a transparent electrode, such as indium tin oxide (ITO).

FIG. 3 illustrates that the dummy pads DP are arranged at one side of the first pad portion PDA1. However, the dummy pads DP are not limited thereto and may be arranged at a different position(s). For example, the dummy pads DP may be arranged between the first signal pads PD1_S. Also, FIG. 3 illustrates that three dummy pads DP are provided. However, the dummy pads DP are not limited thereto, and the number of dummy pads DP may vary.

Referring to FIG. 4, the second pad portion PDA2 may include a plurality of second pads PD2. The second pads PD2 may include second signal pads PD2_S and a plurality of test pads TP.

The second signal pads PD2_S may be electrically connected to the first signal pads PD1_S. The test pads TP may be electrically connected to the dummy pads DP. The second signal pads PD2_S may transmit a signal transmitted from the printed circuit board 50 to the first signal pads PD1_S. The test pads TP may be used together with the dummy pads DP to measure the contact resistance.

The second signal pads PD2_S and the test pads TP may be formed by the same process. The second signal pads PD2_S and the test pads TP may include a conductive material.

FIG. 4 illustrates that the test pads TP are arranged at one side of the second pad portion PDA2. However, the test pads TP are not limited thereto, and may be arranged at a different position. For example, the test pads TP may be arranged between the second signal pads PD2_S. Also, FIG. 4 illustrates that four test pads TP are provided. However, the test pads TP are not limited thereto and the number of test pads TP may vary.

According to one or more embodiments, a test dummy pad and a test test pad, which are objects of a contact resistance test, may be serially connected to each other, and a voltage of a node between the test dummy pad and the test test pad may be measured. Thus, the contact resistance may be measured by using a decreased number of test pads TP. A detailed aspect will be described below.

FIG. 5 is a schematic cross-sectional view of the display apparatus of FIG. 1 taken along the line II_II′, and schematically illustrates a connection portion of the first pads PD1 and the driving integrated circuit 30. The first pads PD1 may be the first signal pads PD1_S or the dummy pads DP.

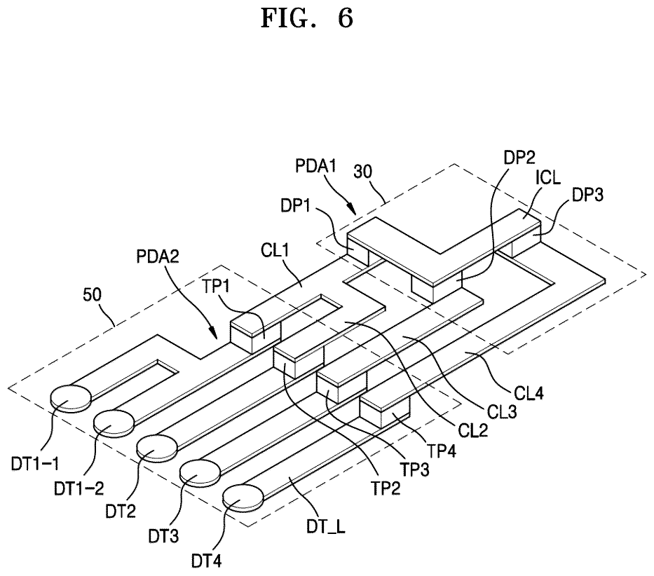

Referring to FIG. 5, the first pads PD1 may be located on the substrate 100 of the display panel. The driving integrated circuit 30 may include a base member SUB_30, and contact pads PD_30 below the base member SUB_30. One or more of the contact pads PD_30 may be short-circuited. One or more of the contact pads PD_30 may be connected to each other by an internal connection line ICL (see FIG. 6) provided in the driving integrated circuit 30.

The first pads PD1 may be bonded to the driving integrated circuit 30 through a conductive adhesive film ACF. The first pads PD1 may be bonded to the contact pads PD_30 of the driving integrated circuit 30. The conductive adhesive film ACF may include an anisotropic conductive film.

The conductive adhesive film ACF may include a plurality of conductive balls BL and an insulating bonding member RN. Each of the plurality of conductive balls BL may include a conductive particle. The conductive particle may be electrically conductive, and may include a particle having conductivity, such as metal or metal oxide, or may include a particle having a core including an insulating material and having a surface coated with metal or metal oxide. The metal may include Ni, Fe, Cu, Al, Sn, Zn, Cr, Co, Ag, or Au. The insulating bonding member RN may include an insulating polymer. The insulating polymer may include, for example, an epoxy resin, an acrylic resin, etc. The epoxy resin has a repeating structure of bisphenol A and ether (—C—O—C—) bonds and may be composed of a phenoxy polymer with an epoxy reactive group at the end. The acrylic resin has a urethane bond (—NHCO—O) connection structure, and may be composed of a urethane (meta) acrylate polymer with an acrylate or methacrylate reactive group at the end.

Contact resistance may occur due to the coupling of the first pad PD1, the conductive ball BL, and the contact pad PD_30 of the driving integrated circuit 30. The contact resistance may be COG resistance or COP resistance (hereinafter, COG/COP resistance) depending on a method of mounting the driving integrated circuit 30 on the display panel.

In one or more embodiments, the printed circuit board 50 (see FIG. 1) may likewise include a base member and contact pads below the base member, and the contact pads of the printed circuit board 50 (see FIG. 1) may be bonded to the second pads PD2 (see FIG. 1) through the conductive adhesive film ACF. Contact resistance may occur due to the coupling of the second pad PD2 (see FIG. 1), the conductive ball BL, and the contact pad of the printed circuit board 50 (see FIG. 1). The contact resistance may be FOG resistance or FOP resistance (hereinafter, FOG/FOP resistance) depending on a method of mounting the printed circuit board 50 (see FIG. 1) on the display panel.

The COG/COP resistance in the pad portion occurring due to the coupling of the driving integrated circuit 30, and the FOG/FOP resistance in the pad portion occurring due to the coupling of the printed circuit board 50, may affect the performance of the display apparatus, and thus, a test of measuring the contact resistance may be required.

FIG. 6 is a perspective view of a connection structure of test terminals, dummy pads, and test pads, configured to measure contact resistance, according to one or more embodiments.

For visibility of a contact portion between the driving integrated circuit 30 and the display panel, and visibility of a contact portion between the printed circuit board 50 and the display panel, FIG. 6 illustrates that the driving integrated circuit 30 is bonded above the display panel, and the printed circuit board 50 is bonded below the display panel. However, the printed circuit board 50 may be bonded on the same surface on which the driving integrated circuit 30 may be bonded. That is, as illustrated in FIG. 1, the driving integrated circuit 30 and the printed circuit board 50 may be bonded on one surface of the display panel 10.

FIG. 6 illustrates the internal connection line ICL provided in the driving integrated circuit 30, a plurality of test terminals and a terminal line DT_L provided in the printed circuit board 50, a plurality of connection lines provided in the display panel 10, the dummy pads, and the test pads. For convenience of illustration, FIG. 6 illustrates that the dummy pads and the driving integrated circuit 30 are in direct contact with each other, and that the test pads and the printed circuit board 50 are in direct contact with each other. However, the contact pad PD_30 (see FIG. 5) of the driving integrated circuit 30 may be located between the dummy pads and the driving integrated circuit 30, and a contact pad of the printed circuit board 50 may be located between the test pads and the printed circuit board 50, in one or more embodiments.

Referring to FIG. 6, the first pad portion PDA1 may include a first dummy pad DP1, a second dummy pad DP2, and a third dummy pad DP3. The first dummy pad DP1, the second dummy pad DP2, and the third dummy pad DP3 may be arranged to be apart from each other. The first dummy pad DP1, the second dummy pad DP2, and the third dummy pad DP3 may be electrically connected to each other.

The second pad portion PDA2 may include a first test pad TP1, a second test pad TP2, a third test pad TP3, and a fourth test pad TP4. The first test pad TP1, the second test pad TP2, the third test pad TP3, and the fourth test pad TP4 may be arranged to be apart from each other.

The display panel may include the plurality of connection lines connecting the test pads and the dummy pads to each other. The plurality of connection lines may include a first connection line CL1 connecting the first test pad TP1 to the first dummy pad DP1, a second connection line CL2 connecting the second test pad TP2 to the first dummy pad DP1, a third connection line CL3 connecting the third test pad TP3 to the second dummy pad DP2, and a fourth connection line CL4 connecting the fourth test pad TP4 to the third dummy pad DP3.

The first connection line CL1, the second connection line CL2, the third connection line CL3, and the fourth connection line CL4 may be formed on the same layer on the substrate 100 (see FIG. 1) of the display panel. The first connection line CL1, the second connection line CL2, the third connection line CL3, and the fourth connection line CL4 may be concurrently or substantially simultaneously formed as one another. The first connection line CL1 and the second connection line CL2 may be integrally formed with each other.

The driving integrated circuit 30 may be mounted on the first pad portion PDA1. The driving integrated circuit 30 may be bonded to the first pad portion PAD1 with the contact pads of the driving integrated circuit 30 corresponding to the dummy pads of the display panel based on one-on-one correspondence.

The driving integrated circuit 30 may include the internal connection line ICL. The internal connection line ICL may be provided in the driving integrated circuit 30 to connect the contact pads of the driving integrated circuit 30 to each other. Thus, the internal connection line ICL may electrically connect the dummy pads to each other. By the internal connection line ICL, the first dummy pad DP1, the second dummy pad DP2, and the third dummy pad DP3 may be electrically connected to each other.

The substrate 100 (see FIG. 1) may be located on a surface of the first dummy pad DP1, the second dummy pad DP2, and the third dummy pad DP3 and the driving integrated circuit 30 may be located on another surface thereof. The first connection line CL1 and/or the second connection line CL2 may be located on (e.g., may contact) a surface of the first dummy pad DP1, and the internal connection line ICL may be located on another surface of the first dummy pad DP1. The third connection line CL3 may be located on (e.g., may contact) a surface of the second dummy pad DP2, and the internal connection line ICL may be located on another surface of the second dummy pad DP2. The fourth connection line CL4 may be located on (e.g., may contact) a surface of the third dummy pad DP3, and the internal connection line ICL may be located on another surface of the third dummy pad DP3. Herein, that an element A is located on a surface of an element B may denote not only that the element A is directly located on the surface of the element B, but also may denote that an element C is located on the surface of the element B while the element A is located on the element C.

The printed circuit board 50 may be mounted on the second pad portion PDA2. The printed circuit board 50 may be bonded to the second pad portion PAD2 with the contact pads of the printed circuit board 50 corresponding to the test pads of the display panel based on one-on-one correspondence. The printed circuit board 50 may include the plurality of test terminals and the terminal line DT_L connecting the plurality of test terminals to the test pads. The plurality of test terminals may apply a current to the test pads or may measure a voltage.

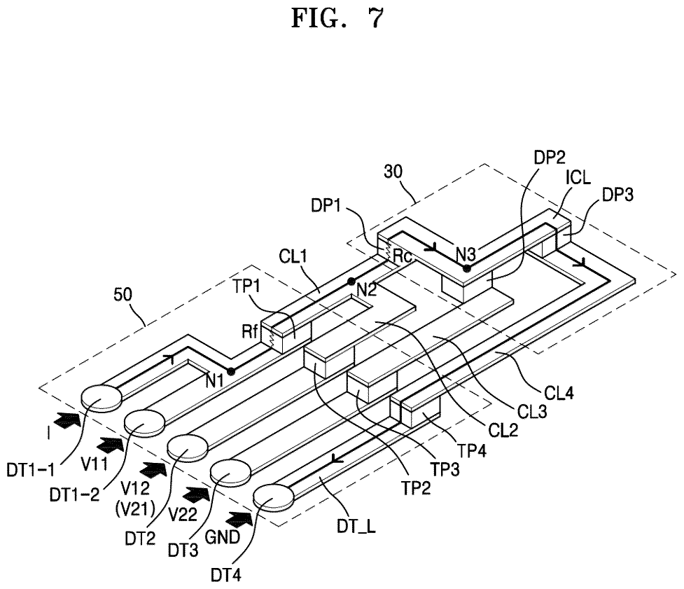

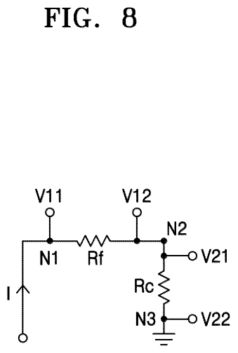

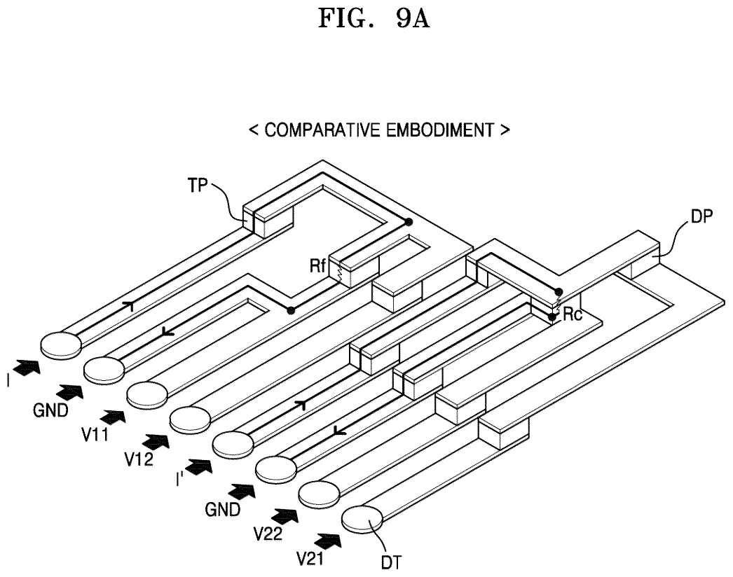

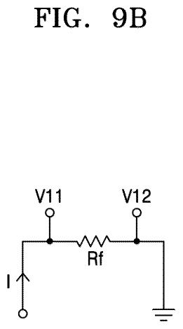

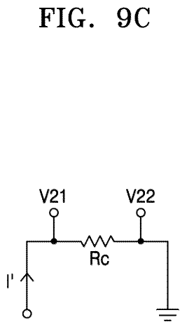

FIG. 7 is a perspective view for describing a method of measuring contact resistance in the connection structure of FIG. 6 and FIG. 8 is a schematic circuit diagram for describing a method of measuring contact resistance of a display apparatus according to one or more embodiments. FIG. 9A is a perspective view for describing a method of measuring contact resistance according to a comparative example and FIGS. 9B and 9C are schematic circuit diagrams for describing the method of measuring the contact resistance according to the comparative one or more embodiments corresponding to the FIG. 9A.

Referring to FIG. 7, the plurality of test terminals may include a 1^{st}-1 test terminal DT1-1, a 1^{st}-2 test terminal DT1-2, a second test terminal DT2, a third test terminal DT3, and a fourth test terminal DT4. The 1^{st}-1 test terminal DT1-1 and the 1^{st}-2 test terminal DT1-2 may be electrically connected to the first test pad TP1, the second test terminal DT2 may be electrically connected to the second test pad TP2, the third test terminal DT3 may be electrically connected to the third test pad TP3, and the fourth test terminal DT4 may be electrically connected to the fourth test pad TP4.

The substrate 100 (see FIG. 1) may be located on a surface of the first test pad TP1, the second test pad TP2, the third test pad TP3, and the fourth test pad TP4 and the printed circuit board 50 may be located on another surface thereof. The first connection line CL1 may be located on a surface of the first test pad TP1, and the terminal line DT_L may be located on (e.g., may contact) another surface thereof. The second connection line CL2 may be located on a surface of the second test pad TP2, and the terminal line DT_L may be located on (e.g., may contact) another surface thereof. The third connection line CL3 may be located on a surface of the third test pad TP3, and the terminal line DT_L may be located on (e.g., may contact) another surface thereof. The fourth connection line CL4 may be located on a surface of the fourth test pad TP4, and the terminal line DT_L may be located on (e.g., may contact) another surface thereof.

According to one or more embodiments, the driving integrated circuit 30 may be mounted on the first pad portion PDA1 by a COG method or a COP method, and the printed circuit board 50 may be mounted on the second pad portion PDA2 by an FOG method or an FOP method.

As described above, as the driving integrated circuit 30 and the printed circuit board 50 are respectively mounted on the pad portions of the display panel, contact resistance may occur. For example, the driving integrated circuit 30 and the first pad PD1 (see FIG. 1) may be in contact with each other, and thus, COG/COP resistance may occur, and as the printed circuit board 50 and the second pad PD2 (see FIG. 1) may be in contact with each other, and thus, FOG/FOP resistance may occur.

FIG. 7 is a view for describing a structure for testing COG/COP resistance and FOG/FOP resistance. In FIG. 7, first contact resistance Rf, which is the FOG/FOP resistance, and second contact resistance Rc, which is the COG/COP resistance are to be tested. The first contact resistance Rf may be contact resistance between the first test pad TP1 and the printed circuit board 50. The second contact resistance Rc may be contact resistance between the first dummy pad DP1 and the driving integrated circuit 30.

Referring to FIG. 7, a test device for testing the first contact resistance Rf and the second contact resistance Rc may be connected to the plurality of test terminals. The first contact resistance Rf and the second contact resistance Rc may be connected to each other in series. According to one or more embodiments, a test current I may be applied to the 1^{st}-1 test terminal DT1-1, and the fourth test terminal DT4 may be grounded. The test current I may be about 1 mA. The test current I applied to the 1^{st}-1 test terminal may get into the fourth test terminal DT4 by sequentially passing through the first test pad TP1, the first dummy pad DP1, the third dummy pad DP3, and the fourth test pad TP4. In other words, the test current I may flow through the terminal line DT_L connected to the 1^{st}-1 test terminal DT1-1, the first contact resistance Rf, the first connection line CL1, the second contact resistance Rc, the internal connection line ICL, the fourth connection line CL4, and the terminal line DT_L connected to the fourth test terminal DT4. Accordingly, the first contact resistance Rf and the second contact resistance Rc may be connected to each other in series.

Referring to FIGS. 7 and 8, the 1^{st}-1 test terminal DT1-2 may be connected to a first node N1 between the 1^{st}-1 test terminal DT1-1 and the first contact resistance Rf. The second test terminal DT2 may be electrically connected to a second node N2 between the first contact resistance Rf and the second contact resistance Rc. The third test terminal DT3 may be electrically connected to a third node N3 between the second contact resistance Rc and the fourth test terminal DT4.

The 1^{st}-2 test terminal DT1-2 may measure a voltage V11 of the first node N1, the second test terminal DT2 may measure a voltage V12 or V21 of the second node N2, and the third test terminal DT3 may measure a voltage V22 of the third node N3. In other words, the 1^{st}-2 test terminal DT1-2 and the second test terminal DT2 may measure voltages of both ends of the first contact resistance Rf. The second test terminal DT2 and the third test terminal DT3 may measure voltages of both ends of the second contact resistance Rc.

A potential difference V11-V12 between the both ends of the first contact resistance Rf measured through the 1^{st}-2 test terminal DT1-2 and the second test terminal DT2 may be divided by a magnitude of the test current I to calculate a magnitude of the first contact resistance Rf. Likewise, a potential difference V21-V22 of both ends of the second contact resistance Rc measured through the second test terminal DT2 and the third test terminal DT3 may be divided by the magnitude of the test current I to calculate a magnitude of the second contact resistance Rc.

FIG. 9A is a view for describing a method of measuring the first contact resistance Rf and the second contact resistance Rc according to a comparative example. FIGS. 9B and 9C are circuit diagrams for describing a method of measuring the first contact resistance Rf and a method of measuring the second contact resistance Rc, respectively.

Referring to FIGS. 9A and 9B, according to the comparative example, a circuit configured to measure the first contact resistance Rf, and a circuit configured to measure the second contact resistance Rc, may be separately provided from each other. According to the comparative example, four test terminals may be used to measure the first contact resistance Rf. The four test terminals may include a terminal configured to apply a test current, a terminal configured for grounding, and two terminals configured to measure a potential difference between both ends of the first contact resistance Rf. Likewise, additional four test terminals may be used to measure the second contact resistance Rc. That is, referring to FIG. 9A, according to the comparative example, to measure both of the first contact resistance Rf and the second contact resistance Rc, the total of eight test terminals and seven test pads may be required.

However, referring to FIG. 7, the display apparatus according to one or more embodiments may measure the first contact resistance Rf and the second contact resistance Rc by using the five test terminals DT1-1, DT1-2, DT2, DT3, and DT4 and the four test pads TP1, TP2, TP3, and TP4. The test current for measuring the first contact resistance Rf and the test current for measuring the second contact resistance Rc may be commonly used. The display apparatus according to one or more embodiments may measure contact resistances by using a decreased number of test pads and test terminals, and thus, an area of the pad portion of the display panel and/or an area of the printed circuit board may be reduced, and the limitation of the design may be decreased. Also, a number of spared test pads or test terminals may be additionally used for a structure for a high potential-difference pad, and thus, robust design may be implemented.

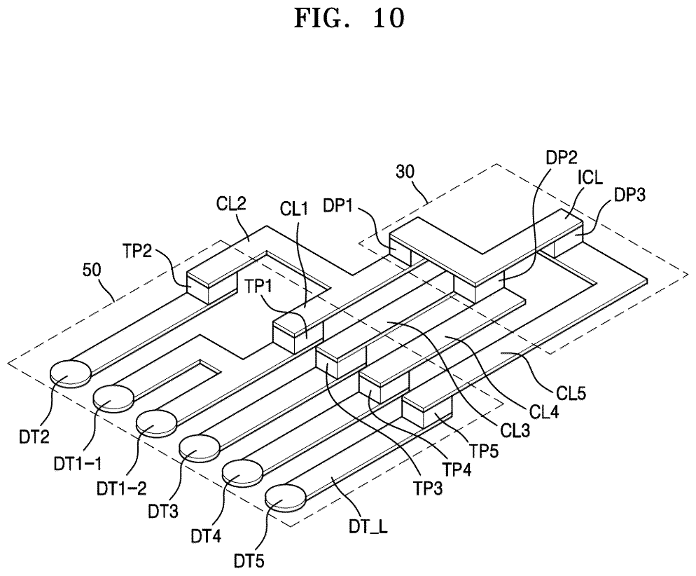

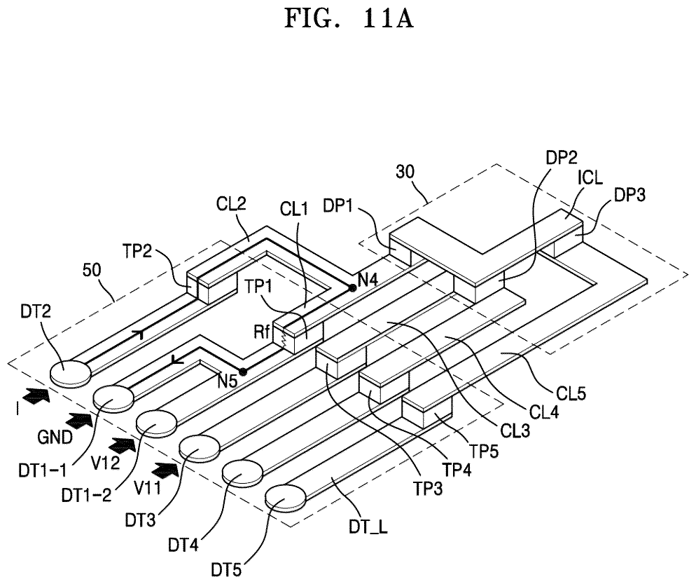

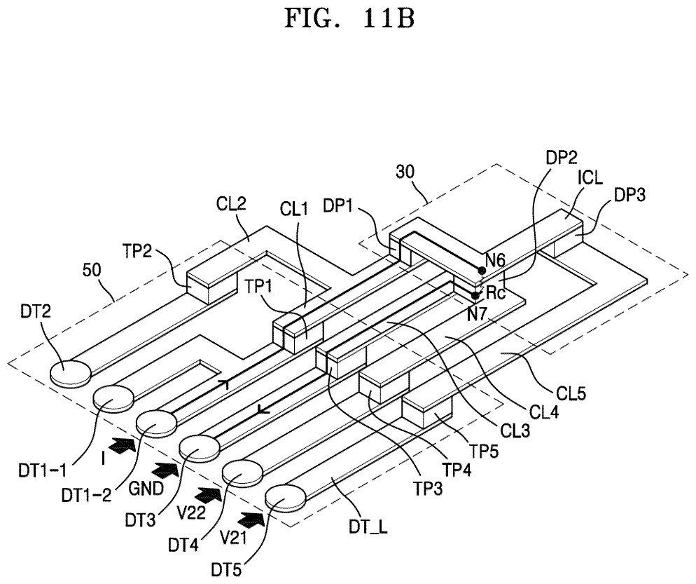

FIG. 10 is a perspective view of a connection structure of test terminals, dummy pads, and test pads according to one or more embodiments and FIGS. 11A and 11B are perspective views for describing a method of measuring contact resistance in the connection structure of FIG. 10. In FIG. 10, reference numerals that are the same as those of FIG. 6 may denote the same elements as those of FIG. 6. Thus, repeated descriptions thereof are omitted and differences are mainly described.

Referring to FIG. 10, according to one or more embodiments, a fifth test pad TP5, a fifth connection line CL5, and a fifth test terminal DT5 may further be included in the one or more embodiments corresponding to the FIG. 6. According to the one or more embodiments corresponding to the FIG. 10, unlike the one or more embodiments corresponding to the FIG. 6, the fourth connection line CL4 may be connected to the second dummy pad DP2, and the fifth connection line CL5 may be connected to the third dummy pad DP3. The third connection line CL3 and the fourth connection line CL4 may be integrally formed with each other.

FIG. 11A is a view for describing a method of measuring first contact resistance Rf according to the one or more embodiments corresponding to the FIG. 10, and FIG. 11B is a view for describing a method of measuring second contact resistance Rc according to the one or more embodiments corresponding to the FIG. 10.

First, referring to FIG. 11A, to measure the first contact resistance Rf, the 1^{st}-1 test terminal DT1-1, the 1^{st}-2 test terminal DT1-2, the second test terminal DT2, and the third test terminal DT3 may be connected to a test device. A test current I may be applied to the second test terminal DT2, and the 1^{st}-1 test terminal DT1-1 may be grounded. The test current I applied to the second test terminal DT2 may get into the 1^{st}-1 test terminal DT1-1 by sequentially passing through the second test pad TP2 and the first test pad TP1. In other words, the test current I may flow through the terminal line DT_L connected to the second test terminal DT2, the second connection line CL2, the first connection line CL1, the first contact resistance Rf, and the terminal line DT_L connected to the 1^{st}-1 test terminal DT1-1.

The third test terminal DT3 may be connected to a fourth node N4 between the second test terminal DT2 and the first contact resistance Rf. The 1^{st}-2 test terminal DT1-2 may be connected to a fifth node N5 between the 1^{st}-1 test terminal DT1-1 and the first contact resistance Rf. The third test terminal DT3 and the 1^{st}-2 test terminal DT1-2 may measure voltages V11 and V12 of both ends of the first contact resistance Rf. A potential difference V11-V12 of the both ends of the first contact resistance Rf, measured through the third test terminal DT3 and the 1^{st}-2 test terminal DT1-2, may be divided by a magnitude of the test current I to calculate a magnitude of the first contact resistance Rf.

Referring to FIG. 11B, to measure the second contact resistance Rc, the 1^{st}-2 test terminal DT1-2, the third test terminal DT3, the fourth test terminal DT4, and the fifth test terminal DT5 may be connected to a test device. A test current I may be applied to the 1^{st}-2 test terminal DT1-2, and the third test terminal DT3 may be grounded. The test current I applied to the 1^{st}-2 test terminal DT1-2 may get into the third test terminal DT3 by sequentially passing through the first test pad TP1, the first dummy pad DP1, the second dummy pad DP2, and the third test pad TP3. In other words, the test current I may flow through the terminal line DT_L connected to the 1^{st}-2 test terminal DT1-2, the first connection line CL1, the internal connection line ICL, the second contact resistance Rc, the third connection line CL3, and the terminal line DT_L connected to the third test terminal DT3.

The fifth test terminal DT5 may be electrically connected to sixth node N6 between the 1^{st}-2 test terminal DT1-2 and the second contact resistance Rc. The fourth test terminal DT4 may be electrically connected to a seventh node N7 between the second contact resistance Rc and the third test terminal DT3. The fifth test terminal DT5 and the fourth test terminal DT4 may measure voltages V21 and V22 of both ends of the second contact resistance Rc. A potential difference V21-V22 across the ends of the second contact resistance Rc measured through the fifth test terminal DT5 and the fourth test terminal DT4 may be divided by a magnitude of the test current I to calculate a magnitude of the second contact resistance Rc.

Referring to FIGS. 10 to 11B, the display apparatus according to one or more embodiments may measure both of the first contact resistance Rf and the second contact resistance Rc by using six test terminals provided in the printed circuit board 50, and five test pads provided in the display panel. Accordingly, designing of the pad portion of the display panel may be improved, and an area of the printed circuit board may be reduced.

According to one or more embodiments as described above, the number of pads for measuring contact resistance between the display panel and the driving integrated circuit or the printed circuit board may be reduced. However, the scope of the disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate defining a display area comprising pixels, and a peripheral area surrounding at least a portion of the display area in plan view;
a first pad portion at a side of the substrate, and comprising dummy pads;
a second pad portion comprising test pads electrically connected to the dummy pads;
a driving integrated circuit electrically connected to the first pad portion; and
a printed circuit board electrically connected to the second pad portion, and comprising test terminals electrically connected to the test pads,
wherein the dummy pads comprise a first dummy pad and a second dummy pad electrically connected to each other by an internal connection line in the driving integrated circuit,
wherein the test pads comprise a first test pad electrically connected to the first dummy pad through a first connection line, a second test pad electrically connected to the first dummy pad through a second connection line, and a third test pad electrically connected to the second dummy pad through a third connection line, and
wherein the test terminals comprise a 1^{st}-1 test terminal and a 1^{st}-2 test terminal that are electrically connected to the first test pad.

2. The display apparatus of claim 1, wherein the dummy pads further comprise a third dummy pad electrically connected to the second dummy pad through the internal connection line, and
wherein the test pads further comprise a fourth test pad electrically connected to the third dummy pad through a fourth connection line.

3. The display apparatus of claim 2, wherein the internal connection line is electrically connected to a surface of the first dummy pad, to a surface of the second dummy pad, and to a surface of the third dummy pad,
wherein the first connection line and the second connection line are electrically connected to another surface of the first dummy pad,
wherein the third connection line is electrically connected to another surface of the second dummy pad, and
wherein the fourth connection line is electrically connected to another surface of the third dummy pad.

4. The display apparatus of claim 2, wherein the test terminals further comprise a second test terminal electrically connected to the second test pad, a third test terminal electrically connected to the third test pad, and a fourth test terminal electrically connected to the fourth test pad.

5. The display apparatus of claim 4, wherein the 1^{st}-2 test terminal is electrically connected to a first node between the 1^{st}-1 test terminal and the first test pad,
wherein the second test terminal is electrically connected to a second node between the first test pad and the first dummy pad, and
wherein the third test terminal is electrically connected to a third node between the first dummy pad and the third dummy pad.

6. The display apparatus of claim 1, wherein the dummy pads further comprise a third dummy pad electrically connected to the second dummy pad through the internal connection line, and
wherein the test pads further comprise a fourth test pad electrically connected to the second dummy pad through a fourth connection line, and a fifth test pad electrically connected to the third dummy pad through a fifth connection line.

7. The display apparatus of claim 6, wherein the internal connection line is electrically connected to a surface of the first dummy pad, to a surface of the second dummy pad, and to a surface of the third dummy pad,
wherein the first connection line and the second connection line are electrically connected to another surface of the first dummy pad,
wherein the third connection line and the fourth connection line are electrically connected to another surface of the second dummy pad, and
wherein the fifth connection line is electrically connected to another surface of the third dummy pad.

8. The display apparatus of claim 6, wherein the test terminals further comprise a second test terminal electrically connected to the second test pad, a third test terminal electrically connected to the third test pad, a fourth test terminal electrically connected to the fourth test pad, and a fifth test terminal electrically connected to the fifth test pad.

9. The display apparatus of claim 8, wherein the second test terminal is connected to a fourth node between the first test pad and the second test pad, and
wherein the 1^{st}-2 test terminal is connected to a fifth node between the 1^{st}-1 test terminal and the first test pad.

10. The display apparatus of claim 8, wherein the fifth test terminal is connected to a sixth node between the first dummy pad and the second dummy pad, and
wherein the fourth test terminal is connected to a seventh node between the second dummy pad and the third test terminal.

11. The display apparatus of claim 1, wherein the dummy pads are insulated from the pixels.

12. The display apparatus of claim 1, wherein the first pad portion comprises first signal pads electrically connected to the pixels, and
wherein the second pad portion comprises second signal pads electrically connected to the first signal pads.

13. The display apparatus of claim 1, wherein the driving integrated circuit comprises contact pads respectively corresponding to the dummy pads.

14. The display apparatus of claim 1, wherein a bending axis is defined between the first pad portion and the pixels, and
wherein the display apparatus is bent with respect to the bending axis.

15. A display apparatus comprising:
pixels;
a first pad portion comprising dummy pads insulated from the pixels;
a second pad portion comprising test pads electrically connected to the dummy pads;
a driving integrated circuit electrically connected to the first pad portion; and
a printed circuit board electrically connected to the second pad portion, and comprising test terminals electrically connected to the test pads,
wherein the dummy pads comprise a first dummy pad, a second dummy pad, and a third dummy pad that are electrically connected to each other through an internal connection line in the driving integrated circuit,
wherein the test pads comprise a first test pad and a second test pad that are electrically connected to the first dummy pad, a third test pad electrically connected to the second dummy pad, and a fourth test pad electrically connected to the third dummy pad, and
wherein the test terminals comprise a 1^{st}-1 test terminal connected to the first test pad, a 1^{st}-2 test terminal connected to a first node between the 1^{st}-2 test terminal and the first test pad, a second test terminal connected to a second node between the first test pad and the first dummy pad, and a third test terminal connected to a third node between the first dummy pad and the third dummy pad.

16. The display apparatus of claim 15, further comprising:
a first connection line connecting the first test pad to the first dummy pad;
a second connection line connecting the second test pad to the first dummy pad;
a third connection line connecting the third test pad to the second dummy pad; and
a fourth connection line connecting the fourth test pad to the third dummy pad.

17. The display apparatus of claim 16, wherein the internal connection line is integrally located on a surface of the first dummy pad, on a surface of the second dummy pad, and on a surface of the third dummy pad,
wherein the first connection line and the second connection line are electrically connected to another surface of the first dummy pad,
wherein the third connection line is electrically connected to another surface of the second dummy pad, and
wherein the fourth connection line is electrically connected to another surface of the third dummy pad.

18. The display apparatus of claim 15, wherein the driving integrated circuit is mounted on the first pad portion by a chip-on-glass (COG) method or a chip-on-plastic (COP) method.

19. The display apparatus of claim 15, wherein the printed circuit board is mounted on the second pad portion by a film-on-glass (FOG) method or a film-on-plastic (FOP) method.

20. The display apparatus of claim 15, wherein the first pad portion comprises first signal pads electrically connected to the pixels, and
wherein the second pad portion comprises second signal pads electrically connected to the first signal pads.
